(19) United States
(12) Patent Application Publication
(10) Pub. No.: US 2025/0298945 A1
(43) Pub. Date: Sep. 25, 2025

(54) TECHNIQUES FOR IMPLEMENTING MACHINE AUTOMATION DESIGNS USING GENERATIVE ARTIFICIAL INTELLIGENCE

(71) Applicant: Xaba Inc., Toronto (CA)

(72) Inventors: Massimiliano MORUZZI, Rockford, IL (US); Francesco IORIO, Toronto (CA)

(21) Appl. No.: 19/085,998

(22) Filed: Mar. 20, 2025

Related U.S. Application Data
(60) Provisional application No. 63/568,337, filed on Mar. 21, 2024.

(51) Int. Cl. G06F 30/27

(52) U.S. Cl. CPC G06F 30/27

(57) ABSTRACT

One embodiment sets forth a technique for generating solutions for machine automation designs. According to some embodiments, the technique includes the steps of receiving an input for a machine automation design; generating, via at least one generative artificial intelligence (AI) model, a design approach for the machine automation design based on the input, where the design approach includes a list of required components for implementing the machine automation design; generating, via the at least one generative AI model, one or more solutions for the machine automation design based on the design approach; displaying, via at least one user interface, information associated with the one or more solutions; receiving or performing a selection of a solution included in the one or more solutions; and performing at least one action in response to receiving the selection of the solution.

### CROSS-REFERENCE TO RELATION APPLICATION

The present application claims the benefit of U.S. Provisional Application titled, “GENERATIVE AI CODE GENERATOR FOR PROGRAMMABLE LOGIC CONTROLLERS”, filed on Mar. 21, 2024, and having Ser. No. 63/568,337. The subject matter of this related application is hereby incorporated herein by reference.

### BACKGROUND

### Field of the Various Embodiments

The contemplated embodiments relate generally to computer science and machine learning and, more specifically, to techniques for implementing machine automation designs using generative artificial intelligence.

### Description of the Related Art

Machine automation design involves designing, implementing, and integrating automated systems that utilize programmable logic controllers (PLCs), sensors, actuators, and other technologies to control and optimize industrial machinery and processes. A PLC is a specialized computing device that can be programmed to execute various control tasks. The flexibility and programmability of PLCs are essential in numerous industrial applications. One category of tasks performed by PLCs includes process control, where PLCs regulate system parameters such as temperature, pressure, and flow. Another category includes machine control, where PLCs manage operations of conveyors, robotic systems, computer numerical control (CNC) machines, and similar equipment.

A first step in machine automation design involves developing a detailed design for the automated system, which includes control systems, sensors, actuators, and mechanical components. A second step involves selecting compatible components from various suppliers to meet design requirements. This selection process requires reviewing specifications of each component from supplier documentation. Once the design is established and compatible components are selected, software code must be developed to control and coordinate the selected components so that the automated system operates according to design specifications.

One drawback of conventional approaches for performing the foregoing steps is that such approaches involve the manual selection of compatible components from numerous suppliers, each offering multiple options with varying specifications. Selecting the appropriate components is challenging because each part has distinct performance characteristics, such as speed, voltage, and power requirements, as well as distinct physical attributes such as dimensions and materials. Furthermore, different suppliers may offer configurations that are incompatible with other selected components, which further-complicates the integration process.

Another drawback of conventional approaches for performing machine automation design concerns the complexity of integrating and configuring different control protocols and communication interfaces. In particular, industrial automation systems often involve components from multiple manufacturers, each using different communication standards such as Modbus, Profibus, or EtherCAT. Enabling interoperability between these components requires significant expertise in industrial networking, control logic synchronization, and real-time data exchange. Additionally, improper configuration of communication protocols can lead to delays, data loss, or system failures, which further-increases the complexity of the design process.

As the foregoing illustrates, there is a need for more efficient and effective techniques for designing and implementing machine automation designs.

### SUMMARY

One embodiment of the present disclosure sets forth a computer implemented method for generating solutions for machine automation designs. According to some embodiments, the method includes the steps of receiving an input for a machine automation design that includes at least one of at least one text prompt or at least one electrical schematic; generating, via at least one generative artificial intelligence (AI) model, a design approach for the machine automation design based on the input, wherein the design approach includes a list of required components for implementing the machine automation design; generating, via the at least one generative AI model, one or more solutions for the machine automation design based on the design approach, wherein each solution included in the one or more solutions is associated with a different set of components that is compatible with the list of required components; displaying, via at least one user interface, information associated with the one or more solutions; receiving or performing a selection of a solution included in the one or more solutions; and performing at least one action in response to receiving the selection of the solution. The at least one action can include, for example, generating source code that configures the set of components associated with the solution to function in accordance with the machine automation design.

Other embodiments of the present disclosure include, without limitation, one or more computer-readable media including instructions for performing one or more aspects of the disclosed techniques as well as a computing device for performing one or more aspects of the disclosed techniques.

One technical advantage of the disclosed techniques over conventional approaches is that the disclosed techniques significantly streamline the process of designing and implementing machine automation systems of varying complexity, thereby making machine automation more accessible to users with different levels of expertise. Using the disclosed techniques, users can specify complex machine automation designs through simple prompts and/or electrical diagrams, which mitigates the need to be well-versed the intricacies of machine automation design. Another technical advantage is that the disclosed techniques leverage machine learning models trained on vast datasets of prior machine automation designs, component manuals, and software code. These trained models can generate complete machine automation designs along with corresponding software code in various programming languages based on minimal user input. As a result, the disclosed techniques alleviate the need for extensive manual effort in system design, component selection, and software development.

Another technical advantage of the disclosed techniques over conventional approaches is that the disclosed techniques automatically select components that are not only suitable for the intended design, but are also compatible with other designs, thereby reducing the risk of design inefficiencies, communication failures, and integration errors. By ensuring interoperability between selected components, the disclosed techniques improve system reliability and performance while minimizing errors and simplifying debugging and troubleshooting efforts. Furthermore, the disclosed techniques can generate multiple design alternatives, as well as associated trade-off metrics, thereby allowing users to evaluate different configurations based on factors such as cost, efficiency, scalability, and power consumption. By presenting these alternatives along with their respective advantages and disadvantages, the disclosed techniques enable users to make more informed design decisions.

These technical advantages collectively provide significant technological improvements over conventional approaches by addressing key challenges in machine automation design and implementations.

### BRIEF DESCRIPTION OF THE DRAWINGS

So that the manner in which the above recited features of the various embodiments can be understood in detail, a more particular description of the inventive concepts, briefly summarized above, may be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 illustrates a block diagram of a computer-based system configured to implement one or more aspects of the various embodiments.

FIG. 2 is a more detailed illustration of the machine automation application of FIG. 1, according to various embodiments.

FIG. 3 illustrates an exemplary user interface that displays key performance indicators (KPIs) for different solutions generated by the machine automation application of FIG. 1, according to various embodiments.

FIG. 4 illustrates an exemplary user interface that displays KPIs for selected parts of a solution generated by the machine automation application of FIG. 1, according to various embodiments.

FIG. 5 is a flow diagram of method steps for generating solutions for machine automation designs, according to some embodiments.

FIG. 6 is a flow diagram of method steps for generating source code that configures a set of components associated with a solution to function in accordance with a machine automation design, according to some embodiments.

FIG. 7 is a more detailed illustration of a computing device that can implement the functionalities of the entities illustrated in FIG. 1, according to various embodiments.

### DETAILED DESCRIPTION

In the following description, numerous specific details are set forth to provide a more thorough understanding of the various embodiments. However, it will be apparent to one skilled in the art that the inventive concepts may be practiced without one or more of these specific details.

### System Overview

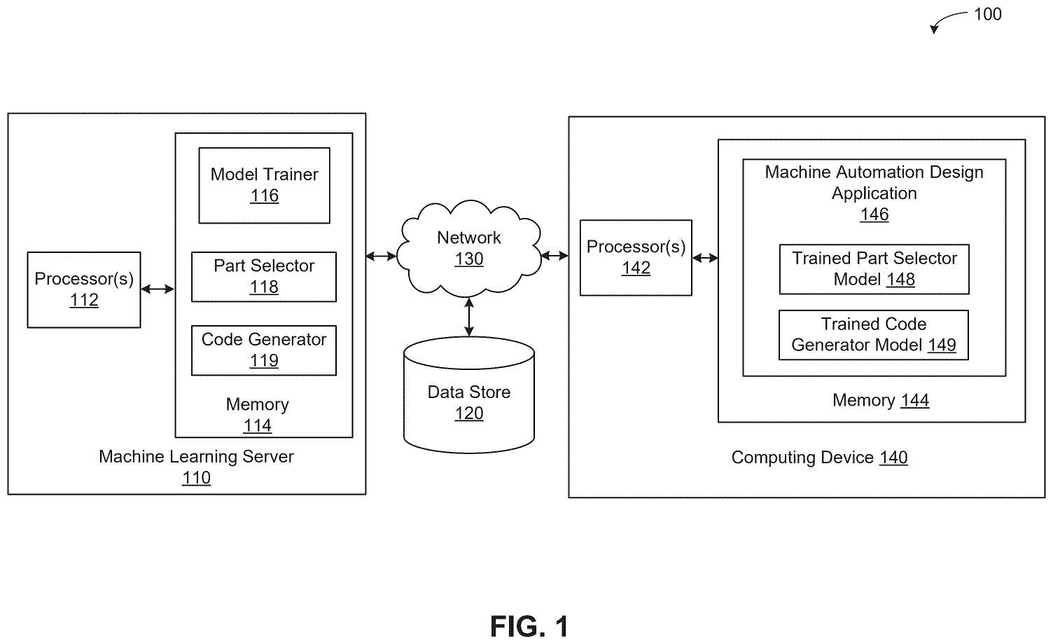

FIG. 1 illustrates a block diagram of a computer-based system 100 configured to implement one or more aspects of the various embodiments. As shown, the system 100 includes a machine learning server 110, a data store 120, and a computing device 140 in communication over a network 130, which can be a wide area network (WAN) such as the Internet, a local area network (LAN), a cellular network, and/or any other suitable network.

According to some embodiments, the machine learning server 110 can include, without limitation, one or more processors 112 and one or more memories 114. The processors 112 execute software applications that receive user input from input devices, such as a keyboard or a mouse. In operation, the processors 112 may include one or more primary processors that control and coordinate the operations of the other system components within the machine learning server 110. In particular, the processor(s) 112 can issue commands that control the operation of one or more graphics processing units (GPUs) (not shown) and/or other parallel processing circuitry (e.g., parallel processing units, deep learning accelerators, etc.) that incorporate circuitry optimized for graphics and video processing, including, for example, video output circuitry. The GPU(s) can deliver pixels to a display device that can be any conventional cathode ray tube, liquid crystal display, light-emitting diode display, and/or the like.

The memory 114 of the machine learning server 110 stores content, such as software applications and data, for use by the processor(s) 112 and the GPU(s) and/or other processing units. The memory 114 can be any type of memory capable of storing data and software applications, such as a random-access memory (RAM), a read-only memory (ROM), an erasable programmable read-only memory (EPROM or Flash ROM), or any suitable combination of the foregoing. In some embodiments, a storage (not shown) is also included in the machine learning server 110. The storage can include any number and type of memories that are accessible to processor 112 and/or the GPU. For example, and without limitation, the storage can include a Secure Digital Card, an external Flash memory, a portable compact disc read-only memory (CD-ROM), an optical storage device, a magnetic storage device, a solid state storage device, and/or any suitable combination of the foregoing.

As shown in FIG. 1, the machine learning server 110 implements a model trainer 116, a part selector 118, and a code generator 119. In various embodiments, model trainer 116 can generate any technically feasible machine learning model, including, but not limited to, neural networks, decision trees, support vector machines, ensemble techniques, and the like. More generally, the various embodiments can extend to any technically feasible generative model and recommendation model architecture.

According to some embodiments, model trainer 116 is configured to generate a trained part selector model 148, e.g., based on the part selector 118. During training, model trainer 116 receives a set of information, such as user inputs, associated design approaches, solutions, etc., from data store 120 or other storage systems, like a cloud storage, NAS drive, or a network storage connected to the machine learning server 110. Model trainer 116 then uses the set of information to generate the trained part selector model 148.

According to some embodiments, model trainer 116 is also configured to generate a trained code generator model 149, e.g., based on the code generator 119. During training, model trainer 116 receives a set of information, such as user inputs, associated design approaches, solutions, and associated code from data store 120 or other storage systems, such as a cloud storage, NAS drive, or a network storage connected to the machine learning server 110. Model trainer 116 then uses the set of information to generate the trained code generator model 149.

In operation, model trainer 116 can dynamically adjust training parameters and methodologies by incorporating a feedback loop that leverages real-time analyses of any performance metric, such as precision, recall, and loss functions. Model trainer 116 can make adjustments to optimize outputs and learned outcomes. These adjustments can include, for example, modifications to learning rates, model architectures, data processing techniques, and the like. In some embodiments, model trainer 116 uses one or more data preprocessors that address common issues such as imbalanced datasets, missing values, and noise, thereby ensuring that the training data for the model being generated, trained, etc., is filtered and representative relative to the problem space in which the model operates. In various embodiments, model trainer 116 uses data augmentation techniques, which can artificially expand the training dataset to improve the generalization capabilities of the model. These features are examples only and are not meant in any way to limit the scope or functionality of model trainer 116.

According to some embodiments, and as described in greater detail herein, trained part selector model 148 initially receives input information, such as a text prompt and/or an electrical schematic provided by a user, for a machine automation design. Trained part selector model 148 then identifies requirements for the machine automation design and generates a design approach with functionality that includes logic operations, associated input/outputs, associated part types, etc. According to some embodiments, trained part selector model 148 identifies key elements of the design approach, such as input/output signals, timers, counters, etc., by analyzing the input information. Trained part selector model 148 then determines the parts with specific parameters that are needed to implement the user requirements. For example, if the machine automation design requires detecting a temperature threshold, then trained part selector model 148 can determine a need for a temperature sensor and select a temperature sensor with compatible input/output modules. Following this, trained part selector model 148 identifies, selects, etc., one or more sets of parts—also referred to herein as solutions—that satisfy the design approach. The solutions can include any electrical, mechanical, etc., parts used for a machine automation design, including CPUs, memory, switches, input/output units, rails, connectors, sensors, actuators, relays, and the like. It is noted that the foregoing examples are not meant to be limiting, and that any number, type, form, etc., of part(s) can be selected by trained part selector model 148, consistent with the scope of this disclosure.

According to some embodiments, trained code generator model 149 receives the generated design approach, selected solution, etc.—which, as described herein, can include logic operations, associated input/outputs, associated parts, and the like. Trained code generator model 149 can identify functionalities of the design approach and the selected solution and then generate code to implement the functionalities. According to some embodiments, the trained code generator model 149 maps the identified design approach and selected solution functionality to specific code having correct syntax, formatting, etc., consistent with one or more machine automation programming languages. The generated code can be any type of machine automation code, including ladder logic, structured text, function block diagrams, sequential function charts, instruction lists, sequential programs, and the like. It is noted that the foregoing examples are not meant to be limiting, and that any amount, type, form, etc., of code can be generated by the trained code generator model 149, consistent with the scope of this disclosure.

As a brief aside, it should be appreciated that the trained part selector model 148 can work in isolation with respect to the trained part selector model 148. In particular, a solution for a given machine automation design can be provided by a user rather than the trained part selector model 148. The user-provided solution can include any amount, type, form, etc., of information, at any level of granularity, that describes, demonstrates, etc., various requirements of a desired machine automation design. For example, the user-provided solution can include text information, image information, video information, file information, etc. In turn, the user-provided solution can be provided to the trained code generator model 149 to generate source code that is compatible with the solution for implementing and achieving the machine automation design.

Turning now to the computing device 140, as shown in FIG. 1, the computing device 140 includes, without limitation, processor(s) 142 and one or more memories 144. Processor(s) 142 receive user input from input devices, such as a keyboard or a mouse. Similar to processor(s) 112 of machine learning server 110, in some embodiments, processor(s) 142 may include one or more primary processors that control and coordinate the operations of the other system components within the computing device 140. In particular, the processor(s) 142 can issue commands that control the operation of one or more graphics processing units (GPUs) (not shown) and/or other parallel processing circuitry (e.g., parallel processing units, deep learning accelerators, etc.) that incorporates circuitry optimized for graphics and video processing, including, for example, video output circuitry. The GPU(s) can deliver pixels to a display device that can be any conventional cathode ray tube, liquid crystal display, light-emitting diode display, and/or the like.

Similar to memory 114 of machine learning server 110, memory 144 of computing device 140 stores content, such as software applications and data, for use by the processor(s) 142 and the GPU(s) and/or other processing units. The memory 144 can be any type of memory capable of storing data and software applications, such as a random-access memory (RAM), a read-only memory (ROM), an erasable programmable read-only memory (EPROM or Flash ROM), or any suitable combination of the foregoing. In some embodiments, a storage (not shown) can supplement or replace the memory 144. The storage can include any number and type of external memories that are accessible to processor 142 and/or the GPU. For example, and without limitation, the storage can include a Secure Digital Card, an external Flash memory, a portable compact disc read-only memory (CD-ROM), an optical storage device, a magnetic storage device, and/or any suitable combination of the foregoing.

As shown in FIG. 1, memory 142 includes a machine automation design application 146 that generates a machine automation design based on user provided inputs through a user interface (not shown), inputs provided programmatically, etc. For example, a user can provide text prompts and/or electrical schematics for a desired machine automation design to machine automation design application 146 via a user interface. Machine automation design application 146 includes trained part selector model 148 and trained code generator model 149. In various embodiments, trained part selector model 148 can be a neural network, a decision tree, a Bayesian network, and the like. In various embodiments, trained code generator model 149 can be an auto-regressive model, such as a decoder-only transformer, a recurrent neural network (RNN), generative pre-trained transformer (GPT), and the like.

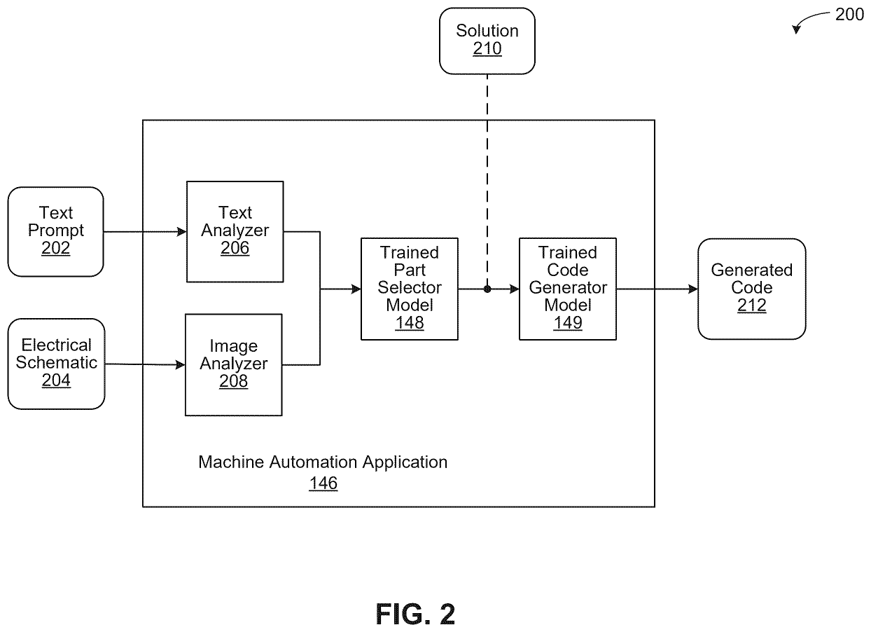

As described herein, machine design automation application 146 uses trained part selector model 148 to generate a design approach based on input information (e.g., text prompts, electrical diagrams, etc.) and establish a list of parts, functionalities, etc., for the generated design approach. Machine design automation application 146 then uses the trained code generator model 149 to generate the specified code for the generated design approach. The operations invoked by machine automation design application 146 when generating design approaches, solutions, and/or machine automation code are described in greater detail below in conjunction with FIGS. 2-6.

Data store 120 provides non-volatile storage for applications and data in machine learning server 110 and computing device 140. For example, and without limitation, training data, trained (or deployed) machine learning models and/or application data, including the trained code generator model 148 and trained part selector model 149 may be stored in the data store 120. In some embodiments, data store 120 may include fixed or removable hard disk drives, flash memory devices, and CD-ROM (compact disc read-only-memory), DVD-ROM (digital versatile disc-ROM), Blu-ray, HD-DVD (high definition DVD), or other magnetic, optical, or solid state storage devices. Data store 120 can be a network attached storage (NAS) and/or a storage area-network (SAN). Although shown as accessible over network 130, in various embodiments, the machine learning server 110 or computing device 140 can include the data store 120.

FIG. 2 is a more detailed illustration 200 of the machine automation design application 146 of FIG. 1, according to various embodiments. As shown, machine automation design application 146 includes, without limitation, a text analyzer 206, an image analyzer 208, as well as the trained part selector model 148 and the trained code generator model 149. In operation, machine automation design application 146 receives text prompt 202 and/or electrical schematic 204 from a user, a software application, etc., for a desired machine automation design via a user interface (not shown), programmatically, or any other approach.

Text prompt 202 can be any written input or other input that is converted into written input (e.g., spoken input), such as a command, a query, a question, etc., that includes the information provided to machine automation design application 146 to select parts and generate machine automation code to satisfy the requirements of a particular machine automation design that is of interest to the user. It is noted that the foregoing examples are not meant to be limiting, and that the text prompt 202 can include any amount, type, form, etc., of information, at any level of granularity, consistent with the scope of this disclosure.

The following is an example of a text prompt 202:

The operational process of a crane involves the use of six push buttons for controlling various functions. The following is an expanded description of the function of each pushbutton.

Start Button: Used to initiate the operation of the crane. When pressed, the start button activates the power supply of the crane and prepares the crane for operation.

Emergency Brake Buttons: Such buttons are designed for emergency situations. When pressed, the emergency brake buttons trigger the emergency braking system of the crane, bringing the crane to a complete stop in case of an emergency or malfunction. Having two emergency brake buttons ensures redundancy and allows for quick access to emergency braking from different locations.

Up Button: Pressing the up button causes the crane to move upward. The up button activates the lifting mechanism of the crane, allowing the crane to raise the load.

Down Button: The down button is used to lower the load held by the crane. When pressed, the down button activates the lowering mechanism, allowing the crane to descend and lower the load safely to the desired position.

Forward Button: Pressing the forward button initiates forward movement of the crane. The forward button engages the drive system of the crane, causing the crane to move in the forward direction along a directionally-forward path.

Backward Button: Similar to the forward button, the backward button is used to initiate backward movement of the crane. When pressed, the backward button activates the reverse drive system of the crane, causing the crane to move backward along a directionally-backward path.

Fully automatic mode operation: In fully automatic mode, movements of the crane shall be entirely controlled by preprogrammed logic within the PLC, with minimal operator intervention. The operator shall input the necessary parameters or commands through a human machine interface (HMI) to initiate the automatic operation.

Turning back now to FIG. 2, electrical schematic 204 can be any diagram that represents the electrical connections, components, such as resistors, capacitors, switches, relays, power sources, and wires in a circuit using standardized symbols. Electrical schematic 204 is provided to machine automation design application 146. Electrical schematic 204 often includes component labels (e.g., R1 for a resistor) and values (e.g., 10Ω) Electrical schematic 204 can be represented in various image formats, such as scalable vector graphics (SVG), portable network graphics (PNG), joint photographic experts group (JPEG), and the like. It is noted that the foregoing examples are not meant to be limiting, and that the electrical schematic 204 can include any amount, type, form, etc., of information, at any level of granularity, consistent with the scope of this disclosure.

According to some embodiments, text analyzer 206 receives and processes the text prompt 202 to extract key elements and to identify information related to the conditions and triggers of the user requested design. The key elements can be input parts, such as sensors, buttons, etc., and output parts, such as motors, lights, alarms, etc. Conditions can be logical or physical states that must be met before an action is executed. Text analyzer 206 can identify conditional operations, such as comparison operations or logical operations to start or to end an action. For example, when a user requests that a motor should turn on only if both a start button (SB) and a safety sensor (SS) are activated, text analyzer 206 identifies a logical AND operation between SB and SS to turn on the motor. As another example, in response to a user request to start a fan if temperature exceeds eighty (80) degrees, text analyzer 206 identifies a comparison operation that checks the temperature and that activates when the temperature exceeds 80 degrees. In some embodiments, text analyzer 206 can identify timer conditions that are based on a certain number of events occurring before an action. Additionally, triggers can be used to control operations, activate devices, start sequences, etc. For example, when a sensor detects an object, a trigger can start a conveyor belt. It is noted that the foregoing examples are not meant to be limiting, and that the text analyzer 206 can identify any amount, type, form, etc., of information included in the text prompt 202, consistent with the scope of this disclosure.

In some embodiments, text analyzer 206 uses a trained natural language processing (NLP) model to identify, analyze, etc., syntax and semantics of the text prompt 202. For example, text analyzer 206 can initially split the text prompt 202 into words or key phrases, also known as tokenization. Text analyzer 206 can then use part-of-speech tagging to assign grammatical roles (e.g., noun, verb, adjective) to each token and subsequently use the trained NLP model to extract key elements using named entity recognition (NER) techniques. In some embodiments, text analyzer 206 can use dependency graphs to parse text prompt 202 and to extract key elements and identify conditions and triggers. In such embodiments, text analyzer 206 generates a dependency graph for text prompt 202. In order to generate a dependency graph, text analyzer 206 tokenizes the text prompt 202 and uses a dependency parsing technique to identify the role of each token in the sentence. The dependency parsing can use any technique to identify each token role. For example, a neural network model composed of three main components—an embedding layer that learns a latent representation of the data given in input to the network, a bidirectional long short-term memory (LSTM) that learns the left to right and right to left relationships between word embeddings, and a biaffine attention layer that enables the model to handle large sequences of data—can be implemented. The key elements, conditions, and triggers can then be extracted and identified using the dependency graphs.

According to some embodiments, image analyzer 208 receives an electrical schematic 204 via a user interface (not shown) and generates a list of electrical components, component labels and values, and connections between the components. Image analyzer 208 loads the electrical schematic 204 using a suitable file reader based on the image format. In order to detect electrical components, image analyzer 208 can perform multiple steps, including preprocessing, feature extraction, and component identification. Image analyzer 208 can use any preprocessing technique to prepare electrical schematic 204, such as binarization, edge detection, noise reduction, and the like. Image analyzer 208 then uses any feasible image processing technique on the preprocessed image to extract features and to detect electrical components. In some embodiments, image analyzer 208 uses a template matching technique to detect predefined electrical components, a contour detection technique to detect electrical component boundaries, or a Hough transform technique to detect lines and circular components (e.g., resistors, capacitors). In some other embodiments, image analyzer 208 can use a trained convolutional neural network (CNN) trained by labeled circuit diagram datasets to detect electrical components. It should be appreciated that the steps described herein may be performed in different orders, and certain steps may be omitted in some embodiments without departing from the scope of this disclosure.

After detecting electrical components, image analyzer 208 can identify labels, values, etc., of each electrical component using optical character recognition (OCR) techniques. For example, OCR can be used to extract text labels, component values, and part numbers in the electrical schematic(s) 204. Image analyzer 208 can initially detect text regions using any feasible technique, such as connected component analysis (CCA) to locate text clusters, contour detection to isolate symbols from labels, and so on. In turn, image analyzer 208 can recognize text within detected text regions using any feasible OCR technique, such as Tesseract OCR or convolutional recurrent neural networks (CRNN). Image analyzer 208 can apply character segmentation if letters or numbers are merged and use language models trained on electrical schematics to identify component labels and values. In some embodiments, text analyzer 208 uses keyword matching for common labels (e.g., “R” for resistors, “C” for capacitors), or apply regular expressions, to extract numerical values (e.g., “100Ω, “110V”). It should be appreciated that the steps described herein may be performed in different orders, and certain steps may be omitted in some embodiments without departing from the scope of this disclosure.

According to some embodiments, and as described herein, connections between electrical components and relationship between the electrical components can also be detected by image analyzer 208. Any feasible technique can be used to detect the connections and identify the relationship between the electrical components. For example, a preprocessing step can be used to binarize the electrical schematic 204 using a specific threshold. Straight and curved connections can then be detected using edge detection. A graph-based approach can be used to identify, map, etc., connections between different electrical components. A graph-based approach can be used to convert the electrical schematic 204 into a netlist format to associate connections with electrical components. Then, search algorithms, such as depth-first search (DFS), breadth-first search (BFS), A-star (A*), etc., can be used in the generated graph to identify connections between the electrical components. It is noted that the foregoing examples are not meant to be limiting, and that any amount, type, form, etc., of information can be analyzed, at any level of granularity, to effectively identify connections and relationships between electrical components, consistent with the scope of this disclosure.

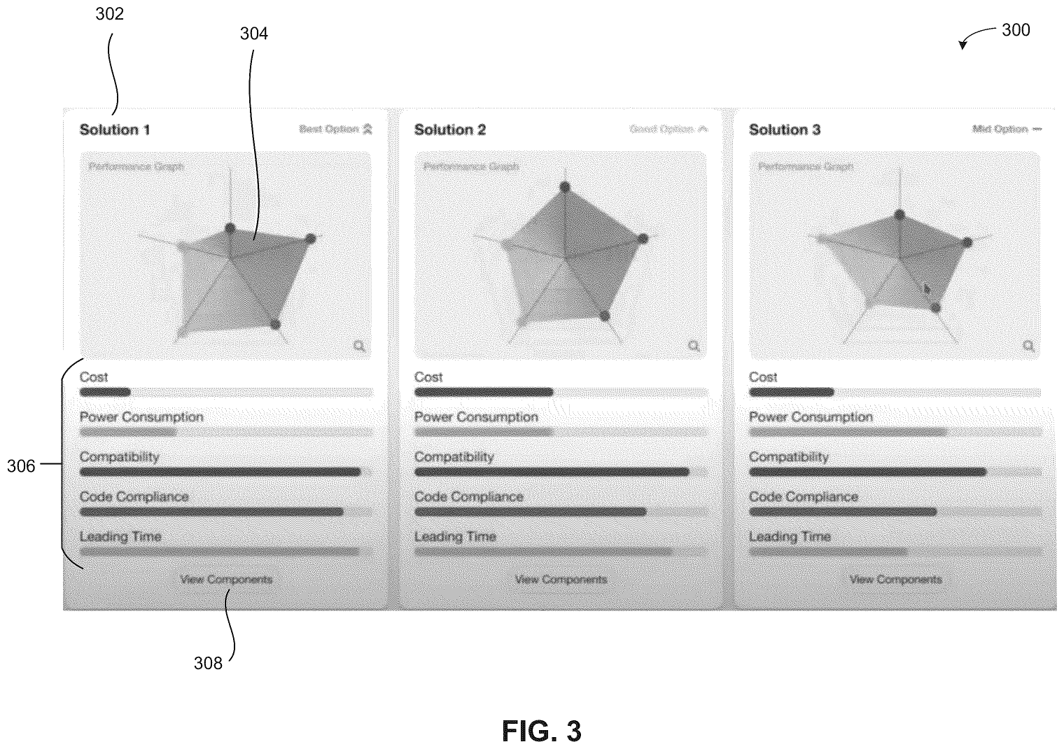

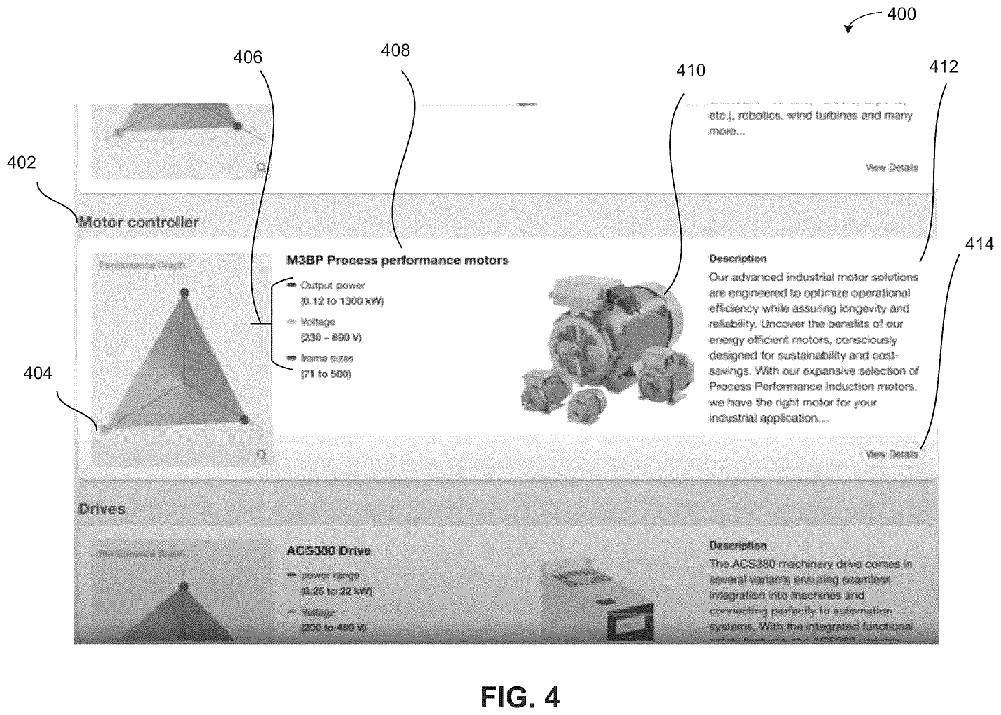

According to some embodiments, and as shown in FIG. 2, trained part selector model 148 receives processed information—also referred to herein as a design approach—from text analyzer 206 and/or image analyzer 208. In turn, the trained part selector model 148 generates, based on the design approach, one or more solutions that satisfy the user requirements of the machine automation design specified in the text prompt 202, the electrical schematic 204, and/or any other relevant information. According to some embodiments, each solution can include logic operations, associated input/outputs, lists of associated parts, etc. According to some embodiments, for each solution, trained part selector model 148 can generate key performance indicators (KPIs) associated with the overall performance of the solution and KPIs for each selected part. The KPIs for the solutions can include metrics for overall costs, power consumptions, compatibilities of parts, compliance with code and regulation requirements, lead times, and the like. The KPIs for each selected part can be specific to each part and can be determined based on specifications provided, for example, in vendor catalogues, websites, etc. For example, for a selected motor controller part, the KPIs can include output power, voltage, frame size, and the like. In some embodiments, the generated solutions and the corresponding KPIs are displayed to the user via a user interface. In such embodiments, the user can select a specific solution via the user interface and observe the details of the parts for that solution. Exemplary KPIs for overall solutions and selected part KPIs are described in greater detail below in conjunction with FIGS. 3 and 4.

According to some embodiments, and as described in greater detail herein, trained code generator model 149 receives the design approach and a selected solution 210, and outputs generated code 212 that is compatible with the selected solution 210 and that implements the functionality requested by the user. Generated code 212 can be any type of machine automation code, including ladder logic, structured text, function block diagrams, sequential function chart, instruction list, sequential program, and the like. It is noted that the foregoing examples are not meant to be limiting, and that any amount, type, form, etc., of code can be generated by the trained code generator model 149, consistent with the scope of this disclosure. Generated code 212 is specific code with correct syntax and formatting consistent with one or more machine automation programming languages. Returning to the example of triggering a fan if the temperature exceeds 80 degrees, the following can be the ladder logic code generated by trained code generator model 149:
//Rung 1:
//—“Temperature Sensor” (Analog input)-->“Read Value” (Instruction to read the analog value)-->“Temperature” (Internal variable to store the read value)
//Rung 2:
//—“Temperature” (Internal variable)-->“Greater Than” (Comparison instruction)-->“80” (Setpoint)
//—If “Greater Than” condition is true, the next rung is activated
Rung 3:
//—“Fan Motor” (Output coil)-->“Energize” (Instruction to turn on the output)

As a brief aside, and, as previously described above in conjunction with FIG. 1, in some embodiments, the trained code generator model 149 can operate independently from the trained part selector model 148. For example, a solution 210 for a given machine automation design can be received, e.g., in situations where the solution for the machine automation design has already been established (e.g., by a user, an engineer, an engineering firm, etc.), where the provider of the solution is seeking to automate the generation of code (i.e., generated code 212) that is compatible with the solution and that, when implemented, causes the solution to operate in accordance with the requirements of the machine automation design. The solution 210 can include any information (e.g., text data, image data, video data, etc.) that provides details about the machine automation design, one or more solutions to the machine automation design, etc., to thereby enable the trained code generator model 149 to effectively generate the generated code 212 for the solution. In some embodiments, the solution 210 can be provided in the same format as or a similar format to the format of the solutions 210 generated by the trained part selector model 148. It is noted that the foregoing examples are not meant to be limiting, and that the solution 210 can include any amount, type, form, etc., of information, at any level of granularity, consistent with the scope of this disclosure.

FIG. 3 illustrates an exemplary user interface 300 that displays KPIs for different solutions generated by the machine automation design application 146 of FIG. 1, according to various embodiments. As shown, the user interface 300 displays three different solution panels 302, where each solution panel 302 includes a performance graph 304, one or more performance metrics 306, and a view components button 308. In some embodiments, the solution panels 302 can be sorted from the best option to the worst option based on a particular metric (e.g., cost, power consumption, overall compatibility, code compliance, leading time, etc.).

As shown in FIG. 3, each performance graph 304 illustrates the overall operational characteristics, efficiency, or effectiveness of a particular solution. Performance graph 304 can represent various performance metrics, such as cost, power consumption, compatibility of selected parts, and the like. It should be appreciated that even though performance graph 304 is illustrated as a radar chart, any other graph capable of illustrating multiple performance metrics 306 can be used, such as pie charts, bar charts, tables, and the like.

According to some embodiments, the performance metrics 306 are quantitative measures used to evaluate the efficiency, effectiveness, capability, etc., of the solutions. According to some embodiments, the performance metrics 306 are determined based on part specifications included in vendor catalogues, websites, etc. As shown in FIG. 3, examples of performance metrics 306 for the solutions can include an overall cost of the selected parts, an overall power consumption of the selected parts, an overall compatibility between the selected parts, an overall compliance with code and regulations for the selected parts, and leading time for the selected parts. It should be appreciated that the performance metrics 306 are illustrative only and that any performance metric can be added to or removed from the user interface depending on the user requested machine automation design, user preferences, etc. According to some embodiments, when the view components button 308 is selected for a given solution, the user interface 300 is replaced with user interface 400 described below in FIG. 4, which illustrates the KPIs for the selected parts of the selected one.

It is noted that the example user interfaces illustrated in FIG. 3 are not meant to be limiting, and that the user interfaces can include any amount, type, form, etc., of information, user interface elements, etc., at any level of granularity, consistent with the scope of this disclosure.

FIG. 4 illustrates an exemplary user interface 400 that displays KPIs for selected parts of a solution generated by the machine automation design application 146 of FIG. 1, according to various embodiments. As shown in FIG. 4, user interface 400 includes different part panels 402, where each part panel 402 includes a performance graph 404, one or more performance metrics 406, a part title 408, a part image 410, a part description 412, and a view details button 414. As shown in FIG. 4, performance graph 404 illustrates the operational characteristics, efficiency, or effectiveness of the selected part, such as a motor controller. Performance graph 404 can represent various performance metrics, such as output power, voltage, frame size, and the like. It should be appreciated that even though performance graph 404 is illustrated as a radar chart, any other graph capable of illustrating multiple performance metrics 406 can be utilized, such as pie charts, bar charts, tables, and the like.

According to some embodiments, the performance metrics 406 are quantitative measures used to evaluate the efficiency, effectiveness, capability, etc., of the selected part. According to some embodiments, the performance metrics 406 are determined based on part specifications included in vendor catalogues, websites, etc. For example, the performance metrics 406 for a motor controller include output power, voltage, and frame size. According to some embodiments, the part title 408 represents the name, description, etc., that appeared in the vendor catalogue, website, etc., for each selected part. Part image 410 demonstrates an image of the part as shown by vendor catalogue. Part description 412 describes a brief specification of the selected part. According to some embodiments, by pressing view details button 414, user interface 400 will be replaced with another user interface that illustrates additional details for the selected part (not shown).

It is noted that the example user interfaces illustrated in FIG. 4 are not meant to be limiting, and that the user interfaces can include any amount, type, form, etc., of information, user interface elements, etc., at any level of granularity, consistent with the scope of this disclosure.

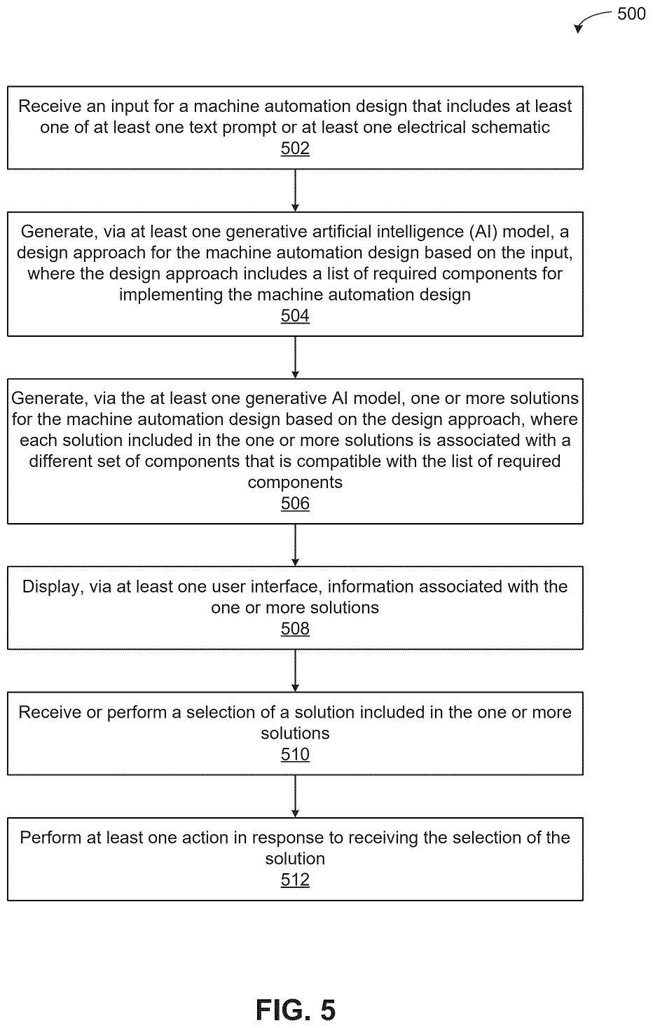

FIG. 5 is a flow diagram of method steps for generating solutions for machine automation designs, according to some embodiments. Although the method steps are described in conjunction with the systems of FIGS. 1-4, persons skilled in the art will understand that any system configured to perform the method steps in any order falls within the scope of the various embodiments.

As shown, a method 500 begins at step 502, where the machine automation design application 146 receives an input for a machine automation design that includes at least one of at least one text prompt or at least one electrical schematic. Text prompt 202 can be any written input or other input that is converted into written input (e.g., spoken input), such as a command, a query, a question, etc., that includes the information provided to machine automation design application 146. Electrical schematic 204 can be any diagram that represents the electrical connections, components, such as resistors, capacitors, switches, relays, power sources, and wires in a circuit using standardized symbols.

At step 504, the machine automation design application 146 generates, via at least one generative AI model, a design approach for the machine automation design based on the input, where the design approach includes a list of required components for implementing the machine automation design.

At step 506, the machine automation design application 146 generates, via the at least one generative AI model, one or more solutions for the machine automation design based on the design approach, where each solution included in the one or more solutions is associated with a different set of components that is compatible with the list of required components. Initially, the user inputs, including text prompt 202 and/or electrical schematic 204 are processed. If provided, text prompt 202 is processed with text analyzer 206 to extract key elements and to identify information related to the conditions and triggers of the requested design. If provided, electrical schematic 204 is processed with image analyzer 208 to generate a list of electrical components, component labels and values, and connections between the components.

At step 508, the machine automation design application 146 displays, via at least one user interface, information associated with the one or more solutions. In some embodiments, the generated solutions and the corresponding information are displayed to the user via a user interface. Information associated with the one or more solutions can include KPIs associated with the overall performance of each solution. The KPIs for the solutions can include overall cost, power consumption, compatibility of selected parts, compliance with the code and regulation requirements, leading time, and the like.

At step 510, the machine automation design application 146 receives or performs a selection of a solution included in the one or more solutions. For example, in response to a selection of a solution in the user interface, the user can observe the details of the parts for that solution. The user interface can then be updated to display the parts and information associated with the parts to the user. Information associated with each selected part can include KPIs associated with the performance of that selected part.

At step 512, the machine automation design application 146 performs at least one action in response to receiving the selection of the solution. In some embodiments, a user can request to see more details associated with each KPI of a selected part. In other embodiments, the user can select an option to generate code (e.g., generated code 212) for the solution that implements the functionality requested by the user. Generated code 212 can be any type of machine automation code, including ladder logic, structured text, function block diagrams, sequential function chart, instruction list, sequential program, and the like.

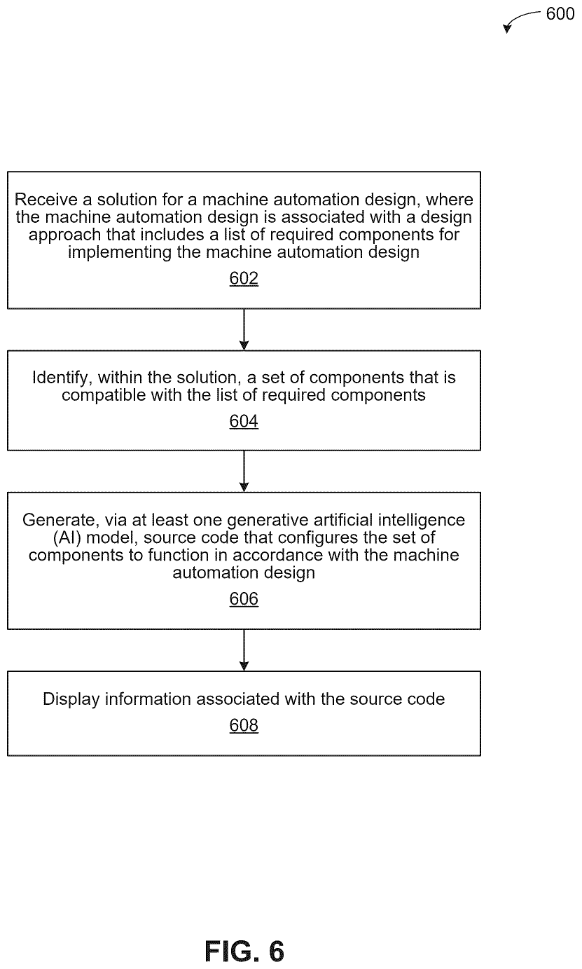

FIG. 6 is a flow diagram of method steps for generating source code that configures a set of components associated with a solution to function in accordance with a machine automation design, according to some embodiments. Although the method steps are described in conjunction with the systems of FIGS. 1-4, persons skilled in the art will understand that any system configured to perform the method steps in any order falls within the scope of the various embodiments.

As shown, a method 600 begins at step 602, where the machine automation design application 146 receives a solution for a machine automation design, where the machine automation design is associated with a design approach that includes a list of required components for implementing the machine automation design. At step 604, the machine automation design application 146 identifies, within the solution, a set of components that is compatible with the list of required components. At step 608, the machine automation design application 146 displays information associated with the source code.

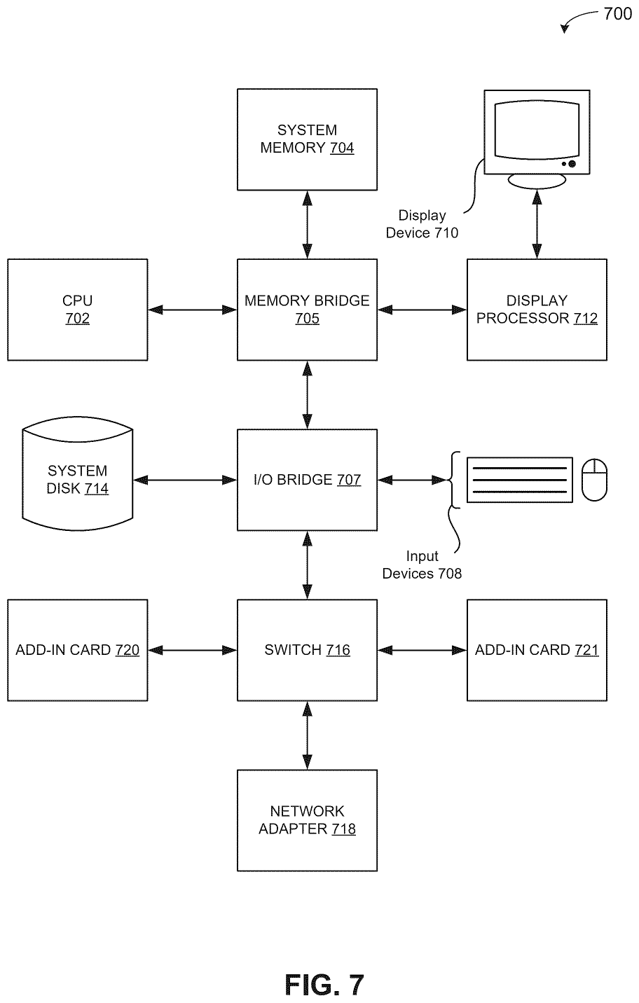

FIG. 7 is a more detailed illustration of a computing device that can implement the functionalities of the entities illustrated in FIG. 1, according to various embodiments. This figure in no way limits or is intended to limit the scope of the various embodiments. In various implementations, system 700 may be an augmented reality, virtual reality, or mixed reality system or device, a personal computer, video game console, personal digital assistant, mobile phone, mobile device or any other device suitable for practicing the various embodiments. Further, in various embodiments, any combination of two or more systems 700 may be coupled together to practice one or more aspects of the various embodiments.

As shown, system 700 includes a central processing unit (CPU) 702 and a system memory 704 communicating via a bus path that may include a memory bridge 705. CPU 702 includes one or more processing cores, and, in operation, CPU 702 is the master processor of system 700, controlling and coordinating operations of other system components. System memory 704 stores software applications and data for use by CPU 702. CPU 702 runs software applications and optionally an operating system. Memory bridge 705, which may be, e.g., a Northbridge chip, is connected via a bus or other communication path (e.g., a HyperTransport link) to an I/O (input/output) bridge 707. I/O bridge 707, which may be, e.g., a Southbridge chip, receives user input from one or more user input devices 708 (e.g., keyboard, mouse, joystick, digitizer tablets, touch pads, touch screens, still or video cameras, motion sensors, and/or microphones) and forwards the input to CPU 702 via memory bridge 705.

A display processor 712 is coupled to memory bridge 705 via a bus or other communication path (e.g., a PCI Express, Accelerated Graphics Port, or HyperTransport link); in one embodiment display processor 712 is a graphics subsystem that includes at least one graphics processing unit (GPU) and graphics memory. Graphics memory includes a display memory (e.g., a frame buffer) used for storing pixel data for each pixel of an output image. Graphics memory can be integrated in the same device as the GPU, connected as a separate device with the GPU, and/or implemented within system memory 704.

Display processor 712 periodically delivers pixels to a display device 710 (e.g., a screen or conventional CRT, plasma, OLED, SED or LCD based monitor or television). Additionally, display processor 712 may output pixels to film recorders adapted to reproduce computer generated images on photographic film. Display processor 712 can provide display device 710 with an analog or digital signal. In various embodiments, one or more of the various graphical user interfaces set forth in FIG. 3 are displayed to one or more users via display device 710, and the one or more users can input data into and receive visual output from those various graphical user interfaces.

A system disk 714 is also connected to I/O bridge 707 and may be configured to store content and applications and data for use by CPU 702 and display processor 712. System disk 714 provides non-volatile storage for applications and data and may include fixed or removable hard disk drives, flash memory devices, and CD-ROM, DVD-ROM, Blu-ray, HD-DVD, or other magnetic, optical, or solid state storage devices.

A switch 716 provides connections between I/O bridge 707 and other components such as a network adapter 718 and various add in cards 720 and 721. Network adapter 718 allows system 700 to communicate with other systems via an electronic communications network, and may include wired or wireless communication over local area networks and wide area networks such as the Internet.

Other components (not shown), including USB or other port connections, film recording devices, and the like, may also be connected to I/O bridge 707. For example, an audio processor may be used to generate analog or digital audio output from instructions and/or data provided by CPU 702, system memory 704, or system disk 714. Communication paths interconnecting the various components in FIG. 7 may be implemented using any suitable protocols, such as PCI (Peripheral Component Interconnect), PCI Express (PCI E), AGP (Accelerated Graphics Port), HyperTransport, or any other bus or point to point communication protocol(s), and connections between different devices may use different protocols, as is known in the art.

In one embodiment, display processor 712 incorporates circuitry optimized for graphics and video processing, including, for example, video output circuitry, and constitutes a graphics processing unit (GPU). In another embodiment, display processor 712 incorporates circuitry optimized for general purpose processing. In yet another embodiment, display processor 712 may be integrated with one or more other system elements, such as the memory bridge 705, CPU 702, and I/O bridge 707 to form a system on chip (SoC). In still further embodiments, display processor 712 is omitted and software executed by CPU 702 performs the functions of display processor 712.

Pixel data can be provided to display processor 712 directly from CPU 702. In some embodiments, instructions and/or data representing a scene are provided to a render farm or a set of server computers, each similar to system 700, via network adapter 718 or system disk 714. The render farm generates one or more rendered images of the scene using the provided instructions and/or data. These rendered images may be stored on computer-readable media in a digital format and optionally returned to system 700 for display. Similarly, stereo image pairs processed by display processor 712 may be output to other systems for display, stored in system disk 714, or stored on computer-readable media in a digital format.

Alternatively, CPU 702 provides display processor 712 with data and/or instructions defining the desired output images, from which display processor 712 generates the pixel data of one or more output images, including characterizing and/or adjusting the offset between stereo image pairs. The data and/or instructions defining the desired output images can be stored in system memory 704 or graphics memory within display processor 712. In an embodiment, display processor 712 includes 3D rendering capabilities for generating pixel data for output images from instructions and data defining the geometry, lighting shading, texturing, motion, and/or camera parameters for a scene. Display processor 712 can further include one or more programmable execution units capable of executing shader programs, tone mapping programs, and the like.

Further, in other embodiments, CPU 702 or display processor 712 may be replaced with or supplemented by any technically feasible form of processing device configured process data and execute program code. Such a processing device could be, for example, a central processing unit (CPU), a graphics processing unit (GPU), an application-specific integrated circuit (ASIC), a field-programmable gate array (FPGA), and so forth. In various embodiments any of the operations and/or functions described herein can be performed by CPU 702, display processor 712, or one or more other processing devices or any combination of these different processors.

CPU 702, render farm, and/or display processor 712 can employ any surface or volume rendering technique known in the art to create one or more rendered images from the provided data and instructions, including rasterization, scanline rendering REYES or micropolygon rendering, ray casting, ray tracing, image-based rendering techniques, and/or combinations of these and any other rendering or image processing techniques known in the art.

In other contemplated embodiments, system 700 may be a robot or robotic device and may include CPU 702 and/or other processing units or devices and system memory 704. In such embodiments, system 700 may or may not include other elements shown in FIG. 7. System memory 704 and/or other memory units or devices in system 700 may include instructions that, when executed, cause the robot or robotic device represented by system 700 to perform one or more operations, steps, tasks, or the like.

It will be appreciated that the system shown herein is illustrative and that variations and modifications are possible. The connection topology, including the number and arrangement of bridges, may be modified as desired. For instance, in some embodiments, system memory 704 is connected to CPU 702 directly rather than through a bridge, and other devices communicate with system memory 704 via memory bridge 705 and CPU 702. In other alternative topologies display processor 712 is connected to I/O bridge 707 or directly to CPU 702, rather than to memory bridge 705. In still other embodiments, I/O bridge 707 and memory bridge 705 might be integrated into a single chip. The particular components shown herein are optional; for instance, any number of add in cards or peripheral devices might be supported. In some embodiments, switch 716 is eliminated, and network adapter 718 and add in cards 720, 721 connect directly to I/O bridge 707.

In sum, the disclosed embodiments set forth techniques for generating machine automation code and selecting compatible parts based on user requirements. A user provides a text prompt and/or an electrical schematic describing the desired machine automation design. Initially, a trained machine learning model processes the text prompt to extract key elements and identify logic operations. If an electrical schematic is provided, the electrical schematic is analyzed using image processing techniques, trained machine learning models, etc., to detect different part types, connections, labels, and values. Following this procedure, another trained machine learning model utilizes the extracted information to generate machine automation code. The generated code can take various forms, including ladder logic, structured text, function block diagrams, sequential function charts, instruction lists, and other machine automation programming formats.

Additionally, the disclosed embodiments employ a trained machine learning model to select a set of parts compatible with both the generated code and the requirements specified by the user. In some embodiments, multiple solutions are generated, each comprising different sets of compatible parts. A user interface is provided to display an overall performance graph for each solution, allowing users to compare the solutions based on key performance indicators (KPIs) and to select a suitable solution. The user interface can also present performance graphs for individual parts within each solution by utilizing data from vendor specification catalogs.

One technical advantage of the disclosed techniques over conventional approaches is that the disclosed techniques significantly streamline the process of designing and implementing machine automation systems of varying complexity, thereby making machine automation more accessible to users with different levels of expertise. Using the disclosed techniques, users can specify complex machine automation designs through simple prompts, which eliminates the need to master the intricacies of machine automation design. Another technical advantage is that the disclosed techniques leverage machine learning models trained on vast datasets of prior machine automation designs, component manuals, and software code. These trained models can generate complete machine automation designs along with corresponding software code in various programming languages based on minimal user input. As a result, the disclosed techniques alleviate the need for extensive manual effort in system design, component selection, and software development.

Another technical advantage of the disclosed techniques over conventional approaches is that the disclosed techniques automatically select components that are not only suitable for the intended design, but are also compatible with other designs, thereby reducing the risk of design inefficiencies, communication failures, and integration errors. By ensuring interoperability between selected components, the disclosed techniques improve system reliability and performance while minimizing errors and simplifying debugging and troubleshooting efforts. Furthermore, the disclosed techniques can generate multiple design alternatives, as well as associated trade-off metrics, thereby allowing users to evaluate different configurations based on factors such as cost, efficiency, scalability, and power consumption. By presenting these alternatives along with their respective advantages and disadvantages, the disclosed techniques enable users to make more informed design decisions.

1. In some embodiments, a computer-implemented method for generating solutions for machine automation designs comprises receiving an input for a machine automation design that includes at least one of at least one text prompt or at least one electrical schematic; generating, via at least one generative artificial intelligence (AI) model, a design approach for the machine automation design based on the input, wherein the design approach includes a list of required components for implementing the machine automation design; generating, via the at least one generative AI model, one or more solutions for the machine automation design based on the design approach, wherein each solution included in the one or more solutions is associated with a different set of components that is compatible with the list of required components; displaying, via at least one user interface, information associated with the one or more solutions; receiving or performing a selection of a solution included in the one or more solutions; and performing at least one action in response to receiving the selection of the solution.

2. The computer-implemented method of clause 1, wherein the at least one action comprises generating source code that configures the set of components associated with the solution to function in accordance with the machine automation design.

3. The computer-implemented method of clause 2, wherein the source code comprises at least one of structured code or ladder logic code.

4. The computer-implemented method of clause 2, further comprising displaying the source code via the at least one user interface; receiving a request to modify the source code; and modifying the source code based on the request.

5. The computer-implemented method of clause 1, wherein the at least one text prompt comprises a description of functional aspects of the machine automation design.

6. The computer-implemented method of clause 1, wherein the at least one electrical schematic comprises an image of functional aspects of the machine automation design.

7. The computer-implemented method of clause 1, wherein the design approach includes requirement information for each component included in the list of required components to implement the machine automation design.

8. The computer-implemented method of clause 1, further comprising generating performance information for each solution included in the one or more solutions; and supplementing the information with the performance information.

9. The computer-implemented method of clause 8, wherein, for each solution included in the one or more solutions, the performance information comprises a key performance indicator (KPI) that includes a plurality of performance metrics.

10. The computer-implemented method of clause 1, further comprising receiving, via at least one user interface element included in the at least one user interface, a request to display information associated with at least one component included in the set of components associated with at least one solution included in the one or more solutions; and displaying the information associated with the at least one component.

11. In some embodiments, one or more non-transitory computer readable media include instructions that, when executed by one or more processors, cause the one or more processors to generate solutions for machine automation designs, by performing the operations of receiving an input for a machine automation design that includes at least one of at least one text prompt or at least one electrical schematic; generating, via at least one generative artificial intelligence (AI) model, a design approach for the machine automation design based on the input, wherein the design approach includes a list of required components for implementing the machine automation design; generating, via the at least one generative AI model, one or more solutions for the machine automation design based on the design approach, wherein each solution included in the one or more solutions is associated with a different set of components that is compatible with the list of required components; displaying, via at least one user interface, information associated with the one or more solutions; receiving or performing a selection of a solution included in the one or more solutions; and performing at least one action in response to receiving the selection of the solution.

12. The one or more non-transitory computer readable media of clause 11, wherein the information comprises at least one of a name of at least one component included in the solution, a manufacturer of the at least one component, a specification of the at least one component, or at least one performance metric associated with the at least one component relative to the machine automation design.

13. The one or more non-transitory computer readable media of clause 11, wherein the operations further include determining, based on at least one of the at least one text prompt, the at least one electrical schematic, or the design approach that at least one modification is required to be made to the design approach; generating modification information for the design approach; and updating the design approach based on the modification information.

14. The one or more non-transitory computer readable media of clause 13, wherein updating the design approach comprises adding at least one component to the list of required components or removing at least one component from the list of required components.

15. The one or more non-transitory computer readable media of clause 11, wherein the at least one action comprises generating source code that configures the set of components associated with the solution to function in accordance with the machine automation design.

16. The one or more non-transitory computer readable media of clause 15, wherein the source code comprises at least one of structured code or ladder logic code.

17. The one or more non-transitory computer readable media of clause 15, wherein the operations further include displaying the source code via the at least one user interface; receiving a request to modify the source code; and modifying the source code based on the request.

18. The one or more non-transitory computer readable media of clause 11, wherein the at least one text prompt comprises a description of functional aspects of the machine automation design.

19. The one or more non-transitory computer readable media of clause 11, wherein the at least one electrical schematic comprises an image of functional aspects of the machine automation design.

20. In some embodiments, a computer system comprises one or more memories that include instructions, and one or more processors that are coupled to the one or more memories, and, when executing the instructions, are configured to generate solutions for machine automation designs, by performing the operations of receiving an input for a machine automation design that includes at least one of at least one text prompt or at least one electrical schematic; generating, via at least one generative artificial intelligence (AI) model, a design approach for the machine automation design based on the input, wherein the design approach includes a list of required components for implementing the machine automation design; generating, via the at least one generative AI model, one or more solutions for the machine automation design based on the design approach, wherein each solution included in the one or more solutions is associated with a different set of components that is compatible with the list of required components; displaying, via at least one user interface, information associated with the one or more solutions; receiving or performing a selection of a solution included in the one or more solutions; and performing at least one action in response to receiving the selection of the solution.

Any and all combinations of any of the claim elements recited in any of the claims and/or any elements described in this application, in any fashion, fall within the contemplated scope of the present disclosure and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

Aspects of the present embodiments may be embodied as a system, method or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “module,” a “system,” or a “computer.” In addition, any hardware and/or software technique, process, function, component, engine, module, or system described in the present disclosure may be implemented as a circuit or set of circuits. Furthermore, aspects of the present disclosure may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine. The instructions, when executed via the processor of the computer or other programmable data processing apparatus, enable the implementation of the functions/acts specified in the flowchart and/or block diagram block or blocks. Such processors may be, without limitation, general purpose processors, special-purpose processors, application-specific processors, or field-programmable gate arrays.

The flowchart and block diagrams in the figures illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

The invention has been described above with reference to specific embodiments. Persons of ordinary skill in the art, however, will understand that various modifications and changes may be made thereto without departing from the broader spirit and scope of the invention as set forth in the appended claims. For example, and without limitation, although many of the descriptions herein refer to specific types of I/O devices that may acquire data associated with an object of interest, persons skilled in the art will appreciate that the systems and techniques described herein are applicable to other types of I/O devices. The foregoing description and drawings are, accordingly, to be regarded in an illustrative rather than a restrictive sense.

While the preceding is directed to embodiments of the present disclosure, other and further embodiments of the disclosure may be devised without departing from the basic scope thereof, and the scope thereof is determined by the claims that follow.

What is claimed is:

1. A computer-implemented method for generating solutions for machine automation designs, the method comprising:
receiving an input for a machine automation design that includes at least one of at least one text prompt or at least one electrical schematic;
generating, via at least one generative artificial intelligence (AI) model, a design approach for the machine automation design based on the input, wherein the design approach includes a list of required components for implementing the machine automation design;
generating, via the at least one generative AI model, one or more solutions for the machine automation design based on the design approach, wherein each solution included in the one or more solutions is associated with a different set of components that is compatible with the list of required components;
displaying, via at least one user interface, information associated with the one or more solutions;
receiving or performing a selection of a solution included in the one or more solutions; and
performing at least one action in response to receiving the selection of the solution.

2. The computer-implemented method of claim 1, wherein the at least one action comprises generating source code that configures the set of components associated with the solution to function in accordance with the machine automation design.

3. The computer-implemented method of claim 2, wherein the source code comprises at least one of structured code or ladder logic code.

4. The computer-implemented method of claim 2, further comprising:
displaying the source code via the at least one user interface;
receiving a request to modify the source code; and
modifying the source code based on the request.

5. The computer-implemented method of claim 1, wherein the at least one text prompt comprises a description of functional aspects of the machine automation design.

6. The computer-implemented method of claim 1, wherein the at least one electrical schematic comprises an image of functional aspects of the machine automation design.

7. The computer-implemented method of claim 1, wherein the design approach includes requirement information for each component included in the list of required components to implement the machine automation design.

8. The computer-implemented method of claim 1, further comprising:
generating performance information for each solution included in the one or more solutions; and
supplementing the information with the performance information.

9. The computer-implemented method of claim 8, wherein, for each solution included in the one or more solutions, the performance information comprises a key performance indicator (KPI) that includes a plurality of performance metrics.

10. The computer-implemented method of claim 1, further comprising:
receiving, via at least one user interface element included in the at least one user interface, a request to display information associated with at least one component included in the set of components associated with at least one solution included in the one or more solutions; and
displaying the information associated with the at least one component.

11. One or more non-transitory computer readable media storing instructions that, when executed by one or more processors, cause the one or more processors to generate solutions for machine automation designs, by performing the operations of:
receiving an input for a machine automation design that includes at least one of at least one text prompt or at least one electrical schematic;
generating, via at least one generative artificial intelligence (AI) model, a design approach for the machine automation design based on the input, wherein the design approach includes a list of required components for implementing the machine automation design;
generating, via the at least one generative AI model, one or more solutions for the machine automation design based on the design approach, wherein each solution included in the one or more solutions is associated with a different set of components that is compatible with the list of required components;
displaying, via at least one user interface, information associated with the one or more solutions;
receiving or performing a selection of a solution included in the one or more solutions; and
performing at least one action in response to receiving the selection of the solution.

12. The one or more non-transitory computer readable media of claim 11, wherein the information comprises at least one of a name of at least one component included in the solution, a manufacturer of the at least one component, a specification of the at least one component, or at least one performance metric associated with the at least one component relative to the machine automation design.

13. The one or more non-transitory computer readable media of claim 11, wherein the operations further include:
determining, based on at least one of the at least one text prompt, the at least one electrical schematic, or the design approach that at least one modification is required to be made to the design approach;
generating modification information for the design approach; and
updating the design approach based on the modification information.

14. The one or more non-transitory computer readable media of claim 13, wherein updating the design approach comprises adding at least one component to the list of required components or removing at least one component from the list of required components.

15. The one or more non-transitory computer readable media of claim 11, wherein the at least one action comprises generating source code that configures the set of components associated with the solution to function in accordance with the machine automation design.

16. The one or more non-transitory computer readable media of claim 15, wherein the source code comprises at least one of structured code or ladder logic code.

17. The one or more non-transitory computer readable media of claim 15, wherein the operations further include:
displaying the source code via the at least one user interface;
receiving a request to modify the source code; and
modifying the source code based on the request.

18. The one or more non-transitory computer readable media of claim 11, wherein the at least one text prompt comprises a description of functional aspects of the machine automation design.

19. The one or more non-transitory computer readable media of claim 11, wherein the at least one electrical schematic comprises an image of functional aspects of the machine automation design.

20. A computer system, comprising:
one or more memories that include instructions; and
one or more processors that are coupled to the one or more memories and, when executing the instructions, are configured to generate solutions for machine automation designs, by performing the operations of:
receiving an input for a machine automation design that includes at least one of at least one text prompt or at least one electrical schematic;
generating, via at least one generative artificial intelligence (AI) model, a design approach for the machine automation design based on the input, wherein the design approach includes a list of required components for implementing the machine automation design;
generating, via the at least one generative AI model, one or more solutions for the machine automation design based on the design approach, wherein each solution included in the one or more solutions is associated with a different set of components that is compatible with the list of required components;
displaying, via at least one user interface, information associated with the one or more solutions;
receiving or performing a selection of a solution included in the one or more solutions; and
performing at least one action in response to receiving the selection of the solution.
